(19) United States
(12) Patent Application Publication
(10) Pub. No.: US 2008/0026585 A1
(43) Pub. Date: Jan. 31, 2008

(54) Composition for removing a film, method of removing a film using the same, and method of forming a pattern using the same

(76) Inventors: Eun-Jeong Kim, Seoul (KR); Seung-Hyun Ahn, Suwon-si (KR); Jung-Eun Kim, Anseong-si (KR); Young-Im Na, Seoul (KR); Baik-Soon Choi, Anyang-si (KR); Dong-Jun Lee, Seoul (KR)

Correspondence Address: HARNESS, DICKEY & PIERCE, P.L.C., P.O. BOX 8910, RESTON, VA, 20195, US

(21) Appl. No.: 11/812,393

(22) Filed: Jun. 19, 2007

(30) Foreign Application Priority Data
Jun. 19, 2006 (KR) 10-2006-0054995

(51) Int. Cl. H01L 21/311; C03C 23/00; G03F 7/42

(52) U.S. Cl. 438/694; 134/2; 510/176; 257/E21.257

(57) ABSTRACT

A film (e.g., silicon polymer film, photoresist film) may be removed by applying a composition including a quaternary ammonium hydroxide, a sulfoxide compound, a dialkylene glycol alkyl ether, and/or water to the film. A silicon polymer film (e.g., hard mask layer) and a photoresist film, for example, may be removed by the composition using an in-situ process. Additionally, the composition may remove the silicon polymer film and the photoresist film while preventing or reducing damage to an underlying layer and the generation of particle-type etch residue.

### PRIORITY STATEMENT

This application claims priority under 35 U.S.C. § 119 to Korean Patent Application No. 10-2006-0054995, filed on Jun. 19, 2006 in the Korean Intellectual Property Office (KIPO), the entire contents of which are incorporated herein by reference.

### BACKGROUND

1. Technical Field

Example embodiments relate to a composition for removing a film, a method of removing a film using the same, and a method of forming a pattern using the same.

2. Description of the Related Art

As the integration of semiconductor devices increases, stricter standards may be required for forming relatively fine patterns via photolithography processes. To form a pattern having a line width of less than about 100 nm, a photoresist pattern having a lower height than a conventional photoresist pattern may be required. However, the lower height of the photoresist pattern may result in a lower etching resistance, and thus the photoresist pattern may not, by itself, suffice as an etching mask for etching an underlying layer. Consequently, the etching resistance of the photoresist pattern may be enhanced by forming a hard mask layer using a carbon or silicon polymer under the photoresist pattern. The hard mask layers may be formed by spin-coating, thus simplifying the formation process while improving the etching resistance of the photoresist pattern.

However, when an ashing process using oxygen plasma, for example, is performed to remove the photoresist pattern, the hard mask layer formed using silicon polymer, for example, may still remain. Therefore, an additional etching process may be required to remove the hard mask layer. However, when an etch-back process using a fluorocarbon gas is performed to remove the hard mask layer, particle-type etch residues may be generated and may result in defects.

### SUMMARY OF EXAMPLE EMBODIMENTS

Example embodiments provide a composition for removing a film (e.g., silicon polymer, photoresist), a method of removing a film from a substrate using the same, and a method of forming a pattern on a substrate using the same.

A composition for removing a film (e.g., silicon polymer, photoresist) may include about 0.1 to about 2 percent by weight of a quaternary ammonium hydroxide, about 5 to about 30 percent by weight of a sulfoxide compound, about 50 to about 84.9 percent by weight of a dialkylene glycol alkyl ether, and about 5 to about 30 percent by weight of water.

The quaternary ammonium hydroxide may include at least one of a tetraalkylammonium hydroxide and a benzyltrimethylammonium hydroxide. The tetraalkylammonium hydroxide may include at least one of tetramethylammonium hydroxide, tetraethylammonium hydroxide, tetrapropylammonium hydroxide, and tetrabutylammonium hydroxide.

The dialkylene glycol alkyl ether may include at least one of diethylene glycol monomethyl ether, diethylene glycol monoethyl ether, diethylene glycol monopropyl ether, diethylene glycol monobutyl ether, dipropylene glycol monomethyl ether, dipropylene glycol monoethyl ether, dipropylene glycol monopropyl ether, and dipropylene glycol monobutyl ether.

A method of removing a film from a substrate may include preparing a composition including about 0.1 to about 2 percent by weight of a quaternary ammonium hydroxide, about 5 to about 30 percent by weight of a sulfoxide compound, about 50 to about 84.9 percent by weight of a dialkylene glycol alkyl ether, and about 5 to about 30 percent by weight of water. A silicon polymer film and a photoresist film may be removed in-situ from the substrate by applying the composition to the silicon polymer film and the photoresist film. The silicon polymer film and the photoresist film may be removed at a temperature of about 20° C. to about 60° C.

A method of forming a pattern on a substrate may include forming an object layer on the substrate. A first hard mask layer may be formed on the object layer using a carbon polymer. A second hard mask pattern may be formed on the first hard mask layer using a silicon polymer. The second hard mask pattern may be formed from a second hard mask layer, which may be formed by a spin-coating process. A first photoresist pattern may be formed on the second hard mask pattern. However, an inspection may reveal a defect in the first photoresist pattern and the second hard mask pattern. Consequently, the first photoresist pattern and the second hard mask pattern may be removed from the first hard mask layer using a composition including about 0.1 to about 2 percent by weight of a quaternary ammonium hydroxide, about 5 to about 30 percent by weight of a sulfoxide compound, about 50 to about 84.9 percent by weight of a dialkylene glycol alkyl ether, and about 5 to about 30 percent by weight of water. The first photoresist pattern and the second hard mask pattern may be removed at a temperature of about 20° C. to about 60° C.

After removing the first photoresist pattern and the second hard mask pattern, a third hard mask pattern may be formed on the first hard mask layer using a silicon polymer. A second photoresist pattern may be formed on the third hard mask pattern. The first hard mask layer may be partially removed using the second photoresist pattern and the third hard mask pattern as etching masks to form a first hard mask pattern on the object layer. The object layer may be partially removed using the third and the first hard mask patterns as etching masks to form an object layer pattern on the substrate.

The third hard mask pattern may be formed by partially etching a third hard mask layer using the second photoresist pattern as an etching mask. For example, partial etching of the third hard mask layer may be performed using a gas including fluorocarbon. The first hard mask layer may be partially removed by an etching process using a gas including oxygen. The second photoresist pattern may be simultaneously removed using the gas including oxygen while the first hard mask layer is partially removed by the etching process. The object layer may be partially removed by an etching process using a gas including fluorocarbon. The third hard mask pattern may be simultaneously removed using the gas including fluorocarbon while the object layer is partially removed by the etching process.

The composition according to example embodiments may remove a silicon polymer film (e.g., hard mask layer) and a photoresist while preventing or reducing damage to an underlying layer and the generation of particle-type etch residue.

### BRIEF DESCRIPTION OF THE DRAWINGS

FIGS. 1 to 6 are cross-sectional views illustrating a method of forming a pattern on a substrate according to example embodiments.

### DETAILED DESCRIPTION OF EXAMPLE EMBODIMENTS

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Example embodiments described herein with reference to cross-section illustrations that are schematic illustrations of idealized embodiments and intermediate structures of the present disclosure. As such, variations from the shapes of the illustrations as a result, for example, of manufacturing techniques and/or tolerances, are to be expected. Thus, example embodiments of the present disclosure should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms including technical and scientific terms used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Composition for Removing a Film

A composition for removing a film (e.g., silicon polymer, photoresist) may include a quaternary ammonium hydroxide, a sulfoxide compound, a dialkylene glycol alkyl ether, and/or water. The composition may include about 0.1 to about 2 percent by weight of a quaternary ammonium hydroxide, about 5 to about 30 percent by weight of a sulfoxide compound, about 50 to about 84.9 percent by weight of a dialkylene glycol alkyl ether, and about 5 to about 30 percent by weight of water.

The composition may include a quaternary ammonium hydroxide. When dissolved in water, the quaternary ammonium hydroxide may generate a hydroxyl group (⁻OH) so as to facilitate the removal of the silicon polymer via an acid-base reaction. The quaternary ammonium hydroxide may include at least one of a tetraalkylammonium hydroxide (e.g., having 1 to 4 carbon atoms) and a benzyltrimethylammonium hydroxide. Examples of the tetraalkylammonium hydroxide may include at least one of tetramethylammonium hydroxide, tetraethylammonium hydroxide, tetrapropylammonium hydroxide, and tetrabutylammonium hydroxide.

When the composition includes less than about 0.1 percent by weight of the quaternary ammonium hydroxide based on the total weight of the composition, the silicon polymer may not be completely removed by the composition. In contrast, when the amount of the quaternary ammonium hydroxide is greater than about 2 percent by weight, an underlying layer (e.g., polysilicon layer) may be damaged. Accordingly, it may be beneficial for the composition to include about 0.1 to about 2 percent by weight of the quaternary ammonium hydroxide.

The composition may include a sulfoxide compound. An example of the sulfoxide compound may include dimethylsulfoxide. The sulfoxide compound may permeate into the silicon polymer and detach the silicon polymer from an underlying layer. When the composition includes less than about 5 percent by weight of the sulfoxide compound based on the total weight of the composition, the sulfoxide compound may not sufficiently penetrate through the silicon polymer, and thus the silicon polymer may not be completely removed. In contrast, when the amount of the sulfoxide compound is greater than about 30 percent by weight, an underlying layer (e.g., polysilicon layer) may be damaged. Accordingly, it may be beneficial for the composition to include about 5 to about 30 percent by weight of the sulfoxide compound.

The composition may include a dialkylene glycol alkyl ether. The dialkylene glycol alkyl ether may enhance the ability of the sulfoxide compound in penetrating and dissolving the silicon polymer. The dialkylene glycol alkyl ether may include at least one of diethylene glycol monomethyl ether, diethylene glycol monoethyl ether, diethylene glycol monopropyl ether, diethylene glycol monobutyl ether, dipropylene glycol monomethyl ether, dipropylene glycol monoethyl ether, dipropylene glycol monopropyl ether, and dipropylene glycol monobutyl ether.

When the composition includes less than about 50 percent by weight of the dialkylene glycol alkyl ether based on the total weight of the composition, the synergistic effect of the sulfoxide compound and the dialkylene glycol alkyl ether with respect to the dissolution of the silicon polymer may be decreased. In contrast, when the amount of the dialkylene glycol alkyl ether is greater than about 84.9 percent by weight, the relative amount of the sulfoxide compound in the composition may be diminished, and thus the effect of the sulfoxide compound in dissolving the silicon polymer may be decreased. Accordingly, it may be beneficial for the composition to include about 50 to about 84.9 percent by weight of the dialkylene glycol alkyl ether.

Examples of water that may be used in the composition may include purified water, ultra-purified water, deionized water, and distilled water. The amount of water included in the composition may be adjusted in consideration of the desired removability of the silicon polymer and the photoresist.

The composition according to example embodiments may remove a silicon polymer film (e.g., hard mask layer) and a photoresist while preventing or reducing damage to an underlying layer and the generation of particle-type etch residue. The composition according to example embodiments may be applied to perform a rework process. When a photoresist pattern and/or a hard mask pattern has a defect (e.g., misalignment), a rework process may be performed to remove the photoresist pattern and the hard mask pattern so as to subsequently form a new photoresist pattern and a new hard mask pattern at the desired position. During the rework process, both the hard mask pattern and the photoresist pattern may be removed using the composition according to example embodiments.

The composition may also be used to form a pattern for semiconductor devices. After the partial removal of a layer using a hard mask pattern and a photoresist pattern as etching masks to form a pattern on a substrate, the hard mask pattern and the photoresist pattern may be removed using the composition according to example embodiments.

Method of Removing a Film from a Substrate

A silicon polymer film and a photoresist film, for example, may be removed by applying a composition including about 0.1 to about 2 percent by weight of a quaternary ammonium hydroxide, about 5 to about 30 percent by weight of a sulfoxide compound, about 50 to about 84.9 percent by weight of a dialkylene glycol alkyl ether, and about 5 to about 30 percent by weight of water to the silicon polymer film and the photoresist film.

The silicon polymer film may be formed under the photoresist film using a photolithography process. The silicon polymer film may be used as a hard mask layer for improving the etching resistance of the photoresist film. During the manufacture of a semiconductor device using a photolithography process, a photoresist pattern may have a defect (e.g., misalignment) such that the photoresist pattern is not formed at the desired position. Consequently, a rework process may be performed so as to remove the misaligned photoresist pattern and silicon polymer film pattern and to form a new photoresist pattern and silicon polymer film pattern at the desired position. During the rework process, both the silicon polymer film pattern and the photoresist pattern may be removed using the composition according to example embodiments.

The quaternary ammonium hydroxide in the composition may play a role in removing a silicon polymer. When dissolved in water, the quaternary ammonium hydroxide may generate a hydroxyl group (⁻OH) so as to facilitate the removal of the silicon polymer via an acid-base reaction. Additionally, the sulfoxide compound may penetrate through the silicon polymer and detach the silicon polymer from an underlying layer (e.g., substrate). Furthermore, the dialkylene glycol alkyl ether may promote the penetration of the sulfoxide compound and the dissolution of the silicon polymer.

The silicon polymer film and the photoresist film may be removed at a temperature of about 20° C. to about 60° C. The silicon polymer film and the photoresist film may also be removed within a relatively short period of time, and the generation of particle-type etch residue may be prevented or reduced. Furthermore, the composition according to example embodiments may prevent or reduce damage to underlying layers or structures. After the silicon polymer film and the photoresist film are removed using the composition, a rinsing process using deionized water and a drying process may be performed to remove any remaining composition from the substrate.

Method of Forming a Pattern on a Substrate

FIGS. 1 to 6 are cross-sectional views illustrating a method of forming a pattern on a substrate according to example embodiments. Referring to FIG. 1, an object layer 110 may be formed on a substrate 100. The object layer 110 may be formed directly on the substrate 100. Alternatively, other structures (e.g., electrode, conductive layer, conductive layer pattern, dielectric layer, dielectric layer pattern) may be formed between the substrate 100 and the object layer 110. The object layer 110 may be patterned to have a desired shape through subsequent processes.

A first hard mask layer 120 may be formed on the object layer 110. The first hard mask layer 120 may be patterned in a subsequent process to form an etching mask for etching the object layer 110. The first hard mask layer 120 may be formed using a carbon polymer. For example, the carbon polymer may include about 80 percent carbon atoms.

A second hard mask layer (not illustrated) may be formed on the first hard mask layer 120. The second hard mask layer (not illustrated) may be formed using a silicon polymer. For example, the second hard mask layer (not illustrated) may be formed by spin-coating the substrate 100 with a solution including a silicon polymer and by hardening the resulting coating film. The coating film may be hardened to remove a solvent and to densify the second hard mask layer (not illustrated).

A first photoresist pattern 140 may be formed on the second hard mask layer (not illustrated). For example, a photoresist film may be formed on the second hard mask layer (not illustrated) by spin-coating the second hard mask layer (not illustrated) to form a resultant photoresist film. A baking process may be performed on the photoresist film, and the photoresist film may be patterned by an exposure process and a developing process to thereby form the first photoresist pattern 140 on the second hard mask layer (not illustrated).

A second hard mask pattern 130 may be formed by etching the second hard mask layer (not illustrated) using the first photoresist pattern 140 as an etching mask. The second hard mask layer (not illustrated) may be etched by a dry etching process. For example, the second hard mask layer (not illustrated) may be etched using a gas including fluorocarbon (CₓF_{y}). The first photoresist pattern 140 may be partially exhausted in the etching process using the gas including fluorocarbon.

An inspection process may be performed on the substrate 100 to detect the presence of defects (e.g., misalignment of the first photoresist pattern 140 and the second hard mask pattern 130). For example, the inspection process may check whether the first photoresist pattern 140 and the second hard mask pattern 130 are formed at a desired position “I”.

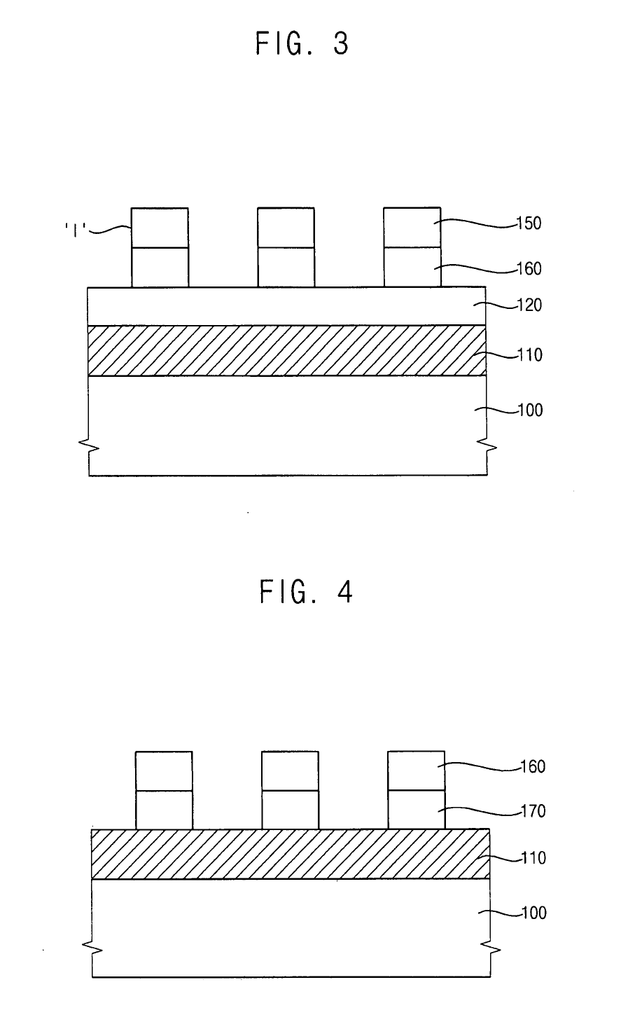

When the first photoresist pattern 140 and the second hard mask pattern 130 are formed at the desired position “I”, the first hard mask layer 120 may be partially removed using the first photoresist pattern 140 and the second hard mask pattern 130 as etching masks by processes described below with reference to FIG. 3.

On the other hand, when the first photoresist pattern 140 and the second hard mask pattern 130 are improperly patterned so as to be formed at an undesired position “II”, a rework process may be performed. In the rework process, the first photoresist pattern 140 and the second hard mask pattern 130 may be removed from the substrate 100, and a new photoresist pattern and a new hard mask pattern may be formed at the desired position “I”.

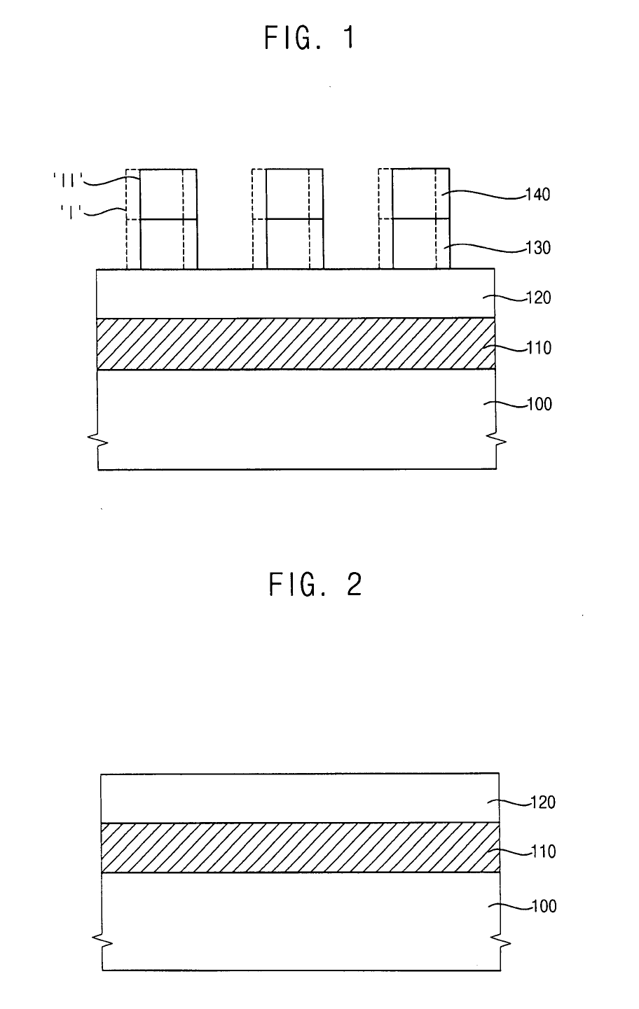

Referring to FIG. 2, in the rework process, the first photoresist pattern 140 and the second hard mask pattern 130 may be removed from the substrate 100 using a composition including about 0.1 to about 2 percent by weight of a quaternary ammonium hydroxide, about 5 to about 30 percent by weight of a sulfoxide compound, about 50 to about 84.9 percent by weight of a dialkylene glycol alkyl ether, and about 5 to about 30 percent by weight of water. For example, the first photoresist pattern 140 and the second hard mask pattern 130 may be removed by immersing the substrate 100 including the first photoresist pattern 140 and the second hard mask pattern 130 into the composition. By using the composition, the first photoresist pattern 140 and the second hard mask pattern 130 may be removed in-situ within a relatively short period of time while preventing or reducing damage to the first hard mask layer 120 and the object layer 110.

The first photoresist pattern 140 and the second hard mask pattern 130 may be removed by using the composition at a temperature of about 20° C. to about 60° C. A rinsing process using deionized water and a drying process may be performed to subsequently remove the remaining composition from the substrate 100.

Referring to FIG. 3, a third hard mask layer (not illustrated) may be formed on the first hard mask layer 120. The third hard mask layer (not illustrated) may be formed using a material similar to that previously used for the second hard mask layer (not illustrated). For example, the third hard mask layer (not illustrated) may be formed using a silicon polymer.

A second photoresist pattern 150 may be formed on the third hard mask layer (not illustrated). For example, a photoresist film may be formed on the third hard mask layer (not illustrated) by spin-coating the substrate 100 with a photoresist composition. The photoresist film may be baked, and the photoresist film may be patterned by an exposure process and a developing process to form the second photoresist pattern 150 on the third hard mask layer (not illustrated).

A third hard mask pattern 160 may be formed by etching the third hard mask layer (not illustrated) using the second photoresist pattern 150 as an etching mask. The third hard mask layer (not illustrated) may be etched by a dry etching process. For example, the third hard mask layer (not illustrated) may be etched using a gas including fluorocarbon (CₓF_{y}).

An inspection process may be performed on the substrate 100 again so as to detect the presence of defects (e.g., misalignment of the second photoresist pattern 150 and the third hard mask pattern 160). The inspection process may check whether the second photoresist pattern 150 and the third hard mask pattern 160 are formed at the desired position “I”. When the second photoresist pattern 150 and the third hard mask pattern 160 are formed at the undesired position “II”, the above-mentioned rework process may be performed again as described with reference to FIGS. 2 and 3. On the other hand, when the second photoresist pattern 150 and the third hard mask pattern 160 are patterned at the desired position “I”, subsequent processes for forming a pattern may be performed.

Referring to FIG. 4, when the second photoresist pattern 150 and the third hard mask pattern 160 are formed at the desired position “I”, the first hard mask layer 120 may be partially removed using the second photoresist pattern 150 and the third hard mask pattern 160 as etching masks to form a first hard mask pattern 170 on the object layer 110. The partial removal of the first hard mask layer 120 may be performed by a dry etching process. For example, the first hard mask layer 120 may be partially removed using a gas including oxygen. While the first hard mask layer 120 is being partially removed using the gas including oxygen, the second photoresist pattern 150 may be simultaneously consumed and removed in-situ as well. Therefore, an additional process for removing the second photoresist pattern 150 may not be needed, thereby simplifying the manufacturing process.

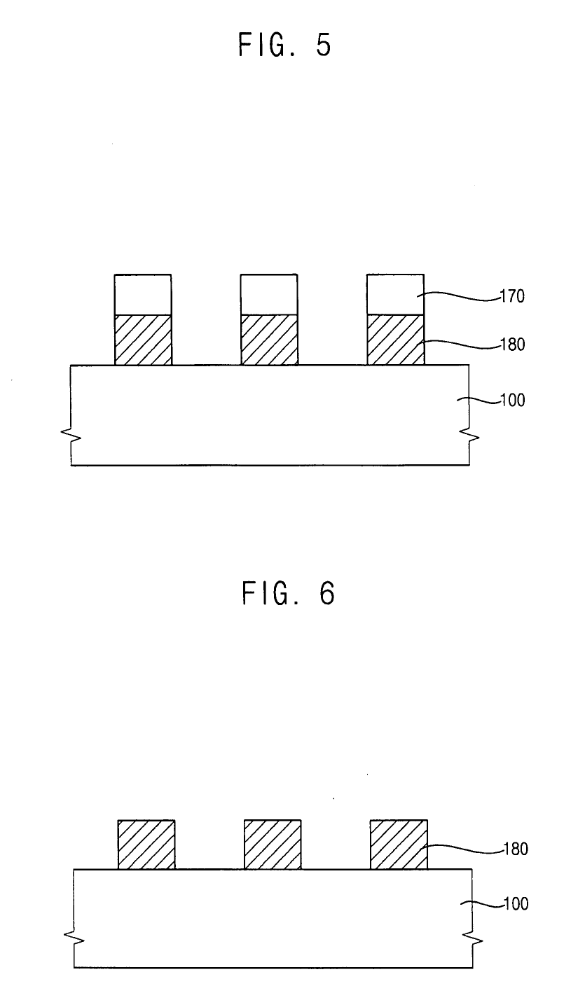

Referring to FIG. 5, the object layer 110 may be partially removed using the third and the first hard mask patterns 160 and 170, respectively, as etching masks to form an object layer pattern 180 on the substrate 100. The partial removal of the object layer 110 may be performed by a dry etching process. For example, the object layer 110 may be partially removed using a gas including fluorocarbon (CₓF_{y}). While the object layer 110 is being partially removed using the gas including fluorocarbon, the third hard mask pattern 160 mask may be consumed and removed in-situ as well. Therefore, an additional process for removing the third hard mask pattern 160 may not be needed.

Referring to FIG. 6, the first hard mask pattern 170 may be removed from the substrate 100. The first hard mask pattern 170 may be removed by an ashing process using a gas including oxygen.

Preparation of a Composition for Removing a Silicon Polymer and a Photoresist

### Example 1

A composition for removing a silicon polymer and a photoresist was prepared by mixing about 0.2 percent by weight of tetramethylammonium hydroxide (TMAH), about 30 percent by weight of dimethylsulfoxide, about 54.8 percent by weight of diethylene glycol monoethyl ether, and about 15 percent by weight of water.

### Example 2

A composition for removing a silicon polymer and a photoresist was prepared by mixing about 0.5 percent by weight of tetramethylammonium hydroxide, about 20 percent by weight of dimethylsulfoxide, about 64.5 percent by weight of diethylene glycol monoethyl ether, and about 15 percent by weight of water.

### Example 3

A composition for removing a silicon polymer and a photoresist was prepared by mixing about 1 percent by weight of tetramethylammonium hydroxide, about 10 percent by weight of dimethylsulfoxide, about 74 percent by weight of diethylene glycol monoethyl ether, and about 15 percent by weight of water.

### Example 4

A composition for removing a silicon polymer and a photoresist was prepared by mixing about 0.2 percent by weight of tetramethylammonium hydroxide, about 30 percent by weight of dimethylsulfoxide, about 54.8 percent by weight of diethylene glycol monobutyl ether, and about 15 percent by weight of water.

### Example 5

A composition for removing a silicon polymer and a photoresist was prepared by mixing about 0.5 percent by weight of tetramethylammonium hydroxide, about 20 percent by weight of dimethylsulfoxide, about 64.5 percent by weight of diethylene glycol monobutyl ether, and about 15 percent by weight of water.

### Example 6

A composition for removing a silicon polymer and a photoresist was prepared by mixing about 1 percent by weight of tetramethylammonium hydroxide, about 10 percent by weight of dimethylsulfoxide, about 74 percent by weight of diethylene glycol monobutyl ether, and about 15 percent by weight of water.

### Comparative Example 1

A composition was prepared by mixing about 5 percent by weight of tetramethylammonium hydroxide, about 50 percent by weight of dimethylsulfoxide, about 20 percent by weight of diethylene glycol monobutyl ether, and about 15 percent by weight of water.

### Comparative Example 2

A composition was prepared by mixing about 0.05 percent by weight of tetramethylammonium hydroxide, about 10 percent by weight of dimethylsulfoxide, about 74.95 percent by weight of diethylene glycol monobutyl ether, and about 15 percent by weight of water.

The types and amounts of the components used for preparing the compositions in Examples 1 to 6 and Comparative Examples 1 and 2 are shown in Table 1.

TABLE 1

| | Types and Amounts of Components [wt %] | | | | |
|---|---|---|---|---|---|
| | | | Dialkylene Glycol | | |
| | | | Alkyl Ether | | |
| | | | Diethylene | Diethylene | |
| | | | Glycol | Glycol | |
| | | Dimethyl | Monoethyl | Monobutyl | |
| | TMAH | sulfoxide | Ether | Ether | Water |
| Example 1 | 0.2 | 30 | 54.8 | — | 15 |
| Example 2 | 0.5 | 20 | 64.5 | — | 15 |
| Example 3 | 1 | 10 | 74 | — | 15 |
| Example 4 | 0.2 | 30 | — | 54.8 | 15 |
| Example 5 | 0.5 | 20 | — | 64.5 | 15 |
| Example 6 | 1 | 10 | — | 74 | 15 |
| Comparative | 5 | 50 | — | 20 | 15 |
| Example 1 | | | | | |
| Comparative | 0.05 | 10 | — | 74.95 | 15 |
| Example 2 | | | | | |

Evaluation of Removability of a Silicon Polymer and a Photoresist

To evaluate removability of a silicon polymer and a photoresist by the composition according to example embodiments, a silicon polymer film was formed on a substrate to have a thickness of about 800 Å. A photoresist film was formed on the silicon polymer film to have a thickness of about 1,600 Å. The substrate including the silicon polymer film and the photoresist film was prepared as a test sample.

A test sample was immersed into each of the compositions prepared in Examples 1 to 6 and Comparative Examples 1 and 2 at a temperature of about 30° C. for a duration of about 30 seconds, about 1 minute, or about 5 minutes. After immersion for the above-mentioned period of time, the test samples were rinsed with ultra-purified water and dried with a nitrogen gas. The dried test samples were examined for the presence of the photoresist film and the silicon polymer film. Examination was performed by macroscopic observation and by scanning electron microscopic (SEM) observation.

The removability of the silicon polymer and the photoresist, by the compositions prepared in Examples 1 to 6 and Comparative Examples 1 and 2, were evaluated as described below. Evaluation results are showed in Table 2. In Table 2, ◯ indicates that the photoresist film and the silicon polymer film were completely removed, Δ means that the photoresist film and the silicon polymer film seemed to be removed under macroscopic observation, but the remains of the photoresist film and the silicon polymer film were observed under SEM observation, and X denotes that the photoresist film and the silicon polymer film were hardly removed.

TABLE 2

| | Immersing Time | | |
|---|---|---|---|
| | 30 seconds | 1 minute | 5 minutes |
| Example 1 | Δ | ◯ | ◯ |
| Example 2 | ◯ | ◯ | ◯ |
| Example 3 | ◯ | ◯ | ◯ |
| Example 4 | Δ | ◯ | ◯ |
| Example 5 | ◯ | ◯ | ◯ |
| Example 6 | ◯ | ◯ | ◯ |
| Comparative Example 1 | ◯ | ◯ | ◯ |
| Comparative Example 2 | X | Δ | ◯ |

As shown in Table 2, all compositions prepared in Examples 1 to 6 removed the photoresist film and the silicon polymer film within about 1 minute.

The composition prepared in Comparative Example 1 also removed the photoresist film and the silicon polymer film. However, the composition prepared in Comparative Example 2 did not remove the photoresist film and the silicon polymer film within 30 seconds but removed the photoresist film and the silicon polymer film after about 5 minutes.

Accordingly, it may be observed that the compositions prepared in Examples 1 to 6 may remove the photoresist film and the silicon polymer film within a period of time shorter than the time required for removing the films using the compositions prepared in Comparative Examples 1 and 2. Notably, the photoresist film and the silicon polymer film took longer to be removed using the composition prepared in Comparative Example 2, which included about 0.05 percent by weight of tetramethylammonium hydroxide, compared with the compositions prepared in Examples 1 to 6. Therefore, it may be confirmed that the amount of tetramethylammonium hydroxide may influence the removability of the photoresist film and the silicon polymer film.

Evaluation of Damages to a Carbon Polymer Film

A substrate including a carbon polymer film was prepared as a test sample to evaluate whether an underlying layer may be damaged by the composition according to example embodiments.

Each test sample was immersed into the compositions that were prepared in Examples 1 to 6 and Comparative Examples 1 and 2 at a temperature of about 30° C. for about 1 minute or about 5 minutes. After being immersed for the above-mentioned period of time, the test samples were rinsed with ultra-purified water and dried with nitrogen gas. The dried test samples were examined for damage to the carbon polymer film. Examination was performed by macroscopic observation and scanning electron microscopic (SEM) observation. The results are showed in Table 3.

In Table 3, ◯ means that there was no damage to the carbon polymer film, A represents that there was some damage to the carbon polymer film, and X indicates that there was serious damage to the carbon polymer film.

TABLE 3

Immersing Time

| | 1 Minute | 5 Minutes |
|---|---|---|
| Example 1 | ◯ | ◯ |
| Example 2 | ◯ | ◯ |
| Example 3 | ◯ | ◯ |
| Example 4 | ◯ | ◯ |
| Example 5 | ◯ | ◯ |
| Example 6 | ◯ | ◯ |
| Comparative Example 1 | X | X |
| Comparative Example 2 | ◯ | ◯ |

As shown in Table 3, all compositions prepared in Examples 1 to 6 did not damage the carbon polymer film. While the composition prepared in Comparative Example 2 did not damage the carbon polymer film, the composition prepared in Comparative Example 1 seriously damaged the carbon polymer film.

From Tables 2 and 3, it may be observed that as the amount of the tetramethylammonium hydroxide increases, the removability of the photoresist film and the silicon polymer film may be enhanced, but damage to the carbon polymer film may also increase.

Evaluation of Damages to a Polysilicon Layer

To evaluate whether an underlying layer may be damaged by the composition according to example embodiments, a substrate including a polysilicon layer was prepared as a test sample.

Each test sample was immersed into the compositions that were prepared in Examples 1 to 6 and Comparative Examples 1 and 2 at a temperature of about 30° C. for about 30 minutes. After being immersed for the above-mentioned period of time, the test samples were rinsed with ultra-purified water and dried with a nitrogen gas. The dried test samples were examined for damage to the polysilicon layer. Examination was performed by macroscopic observation and scanning electron microscopic (SEM) observation. Evaluation results are shown in Table 4.

In Table 4, ◯ represents that there was no damage to the polysilicon layer, A means that there were some damage to the polysilicon layer, and X indicates that there was serious damage to the polysilicon layer.

TABLE 4

| | Evaluated Damages to the Polysilicon Layer |
|---|---|
| Example 1 | ◯ |
| Example 2 | ◯ |
| Example 3 | ◯ |
| Example 4 | ◯ |
| Example 5 | ◯ |
| Example 6 | ◯ |
| Comparative Example 1 | Δ |
| Comparative Example 2 | ◯ |

Referring to Table 4, all compositions prepared in Examples 1 to 6 did not damage the polysilicon layer. Although the composition prepared in Comparative Example 2 did not damage the polysilicon layer, the composition prepared in Comparative Example 1 damaged the polysilicon layer.

Based on Tables 2 and 4, it may be confirmed that as the amount of the tetramethylammonium hydroxide increases, the removability of the photoresist film and the silicon polymer film may increase, but damage to the polysilicon layer may also increase.

While example embodiments have been disclosed herein, it should be understood that other variations may be possible. Such variations are not to be regarded as a departure from the spirit and scope of example embodiments of the present disclosure, and all such modifications as would be obvious to one skilled in the art are intended to be included within the scope of the following claims.

What is claimed is:

1. A composition for removing a film, comprising:
about 0.1 to about 2 percent by weight of a quaternary ammonium hydroxide;
about 5 to about 30 percent by weight of a sulfoxide compound;
about 50 to about 84.9 percent by weight of a dialkylene glycol alkyl ether; and
about 5 to about 30 percent by weight of water.

2. The composition of claim 1, wherein the quaternary ammonium hydroxide includes at least one of a tetraalkylammonium hydroxide and benzyltrimethylammonium hydroxide.

3. The composition of claim 2, wherein the tetraalkylammonium hydroxide includes at least one selected from the group consisting of tetramethylammonium hydroxide, tetraethylammonium hydroxide, tetrapropylammonium hydroxide, and tetrabutylammonium hydroxide.

4. The composition of claim 1, wherein the sulfoxide compound includes dimethylsulfoxide.

5. The composition of claim 1, wherein the dialkylene glycol alkyl ether includes at least one selected from the group consisting of diethylene glycol monomethyl ether, diethylene glycol monoethyl ether, diethylene glycol monopropyl ether, diethylene glycol monobutyl ether, dipropylene glycol monomethyl ether, dipropylene glycol monoethyl ether, dipropylene glycol monopropyl ether, and dipropylene glycol monobutyl ether.

6. The composition of claim 1, wherein the water includes at least one selected from the group consisting of purified water, deionized water, and distilled water.

7. A method of removing a film from a substrate, comprising:
preparing a composition including about 0.1 to about 2 percent by weight of a quaternary ammonium hydroxide, about 5 to about 30 percent by weight of a sulfoxide compound, about 50 to about 84.9 percent by weight of a dialkylene glycol alkyl ether and about 5 to about 30 percent by weight of water; and
in-situ removing a silicon polymer film and a photoresist film from the substrate by applying the composition to the silicon polymer film and the photoresist film.

8. The method of claim 7, wherein the silicon polymer film and the photoresist film are removed at a temperature of about 20° C. to about 60° C.

9. The method of claim 7, wherein the silicon polymer film and the photoresist film are used as etching masks.

10. A method of forming a pattern on a substrate, comprising:
forming an object layer on the substrate;
forming a first hard mask layer on the object layer;
forming a second hard mask pattern on the first hard mask layer;
forming a first photoresist pattern on the second hard mask pattern;
detecting a defect of the first photoresist pattern and the second hard mask pattern; and
removing the first photoresist pattern and the second hard mask pattern from the first hard mask layer using a composition including about 0.1 to about 2 percent by weight of a quaternary ammonium hydroxide, about 5 to about 30 percent by weight of a sulfoxide compound, about 50 to about 84.9 percent by weight of a dialkylene glycol alkyl ether, and about 5 to about 30 percent by weight of water.

11. The method of claim 10, wherein the first hard mask layer is formed of a carbon polymer.

12. The method of claim 10, wherein the second hard mask pattern is formed of a silicon polymer.

13. The method of claim 10, wherein the first photoresist pattern and the second hard mask pattern are removed at a temperature of about 20° C. to about 60° C.

14. The method of claim 10, further comprising:
forming a third hard mask pattern on the first hard mask layer;
forming a second photoresist pattern on the third hard mask pattern;
partially removing the first hard mask layer using the second photoresist pattern and the third hard mask pattern as etching masks to form a first hard mask pattern on the object layer; and
partially removing the object layer using the third and the first hard mask patterns as etching masks to form an object layer pattern on the substrate.

15. The method of claim 14, wherein the third hard mask pattern is formed of a silicon polymer.

16. The method of claim 14, wherein the first hard mask layer is partially removed by an etching process using a gas including oxygen.

17. The method of claim 16, wherein the second photoresist pattern is simultaneously removed using the gas including oxygen while the first hard mask layer is partially removed by the etching process.

18. The method of claim 14, wherein the object layer is partially removed by a dry etching process.

19. The method of claim 18, wherein the etching process uses a gas including fluorocarbon

20. The method of claim 19, wherein the third hard mask pattern is simultaneously removed using the gas including fluorocarbon while the object layer is partially removed by the etching process.
